(19) United States
(12) Patent Application Publication
(10) Pub. No.: US 2016/0133485 A1
(43) Pub. Date: May 12, 2016

(54) SYSTEMS AND METHODS FOR IN-LINE MEASUREMENT OF PRE-UNDERFILL WETTING ANGLE

(71) Applicant: Compass Electro Optical Systems Ltd., Netanya, IL (US)

(72) Inventors: Yehoshua Shuki BENJAMIN, Shimshit (IL); Avi MAMAN, Herzlia (IL)

(21) Appl. No.: 14/536,982

(22) Filed: Nov. 10, 2014

(51) Int. Cl. H01L 21/56; H01L 21/66; H01L 23/00; H01L 21/67

(52) U.S. Cl. CPC H01L 21/563; H01L 21/67126; H01L 21/67259; H01L 22/20; H01L 24/81; H01L 2224/81122; H01L 2224/16225

(57) ABSTRACT

Systems and method for determining whether to apply a liquid adhesive to a chip substrate based on a measured wetting angle are disclosed. According to the disclosed systems and methods, the chip substrate is treated, for example, by cleaning and activating the chip substrate surface with energetic plasma. One or more liquid adhesive drops are dispensed on the treated chip substrate surface. A camera captures a top-down image of the one or more liquid adhesive drops. The wetting angle between the liquid adhesive drops is calculated based on the image and volume data of the liquid adhesive drops. A layer of the liquid adhesive is applied to the chip substrate based on the calculated wetting angle and predetermined parameters.

### FIELD OF THE INVENTION

The present disclosure relates to chip packaging, and more specifically to monitoring underfill application process.

### BACKGROUND

When manufacturing an application-specific integrated circuit (ASIC) semi-conductor package, each integrated circuit chip must be electrically and physically connected to the rest of the package. One common technique for establishing the connection between a particular chip and the rest of the package is called the “flip chip” technique, where the surface of the chip that is etched with circuitry is “flipped” to face the surface of the package die that is likewise etched. According to this technique, a solder material is placed on the chip (either as solder bumps or metal pillars with a soldering agent—i.e. tin—on the top) to provide electrical connections between the circuitry on the chip substrate and the circuitry on the package die. The chip is then connected to the packaging circuitry by aligning them, heating to the eutectic temperature and soldering the chip to the package die. An electrically-insulated adhesive, also known as underfill, is then applied between the chip substrate and the package die substrate, in and around the solder bumps, to securely adhere the chip to the package, provide insulation between the solder bumps and increase the reliability of the connection and its robustness to environmental conditions such as temperature cycling.

The dispensing of underfill is common in modern state-of-the-art “flip chip” packaging assembly lines, and the successful adhesion of the underfill to the chip substrate and to the package increases package reliability. Package reliability is more challenging in large package sizes, such as those greater than 150 mm², where the stress due to the differences in the Coefficient of Thermal Expansion (CTE) creates large differential forces and can cause high stress on the “flip chip” assembly dies and soldered connections.

If the adhesion of the underfill is weak, during the high temperature manufacturing steps following the “flip chip” connection, there is a risk of underfill delamination in which part of the underfill material separates from the chip substrate or from the package. This separation creates a crack or void in the insulating underfill. This, in turn, can result in improper insulation between adjacent solder bumps, causing one or more electrical shorts in the circuit or an increased stress at the point of failure and corresponding yield loss in the package or reduced reliability over time.

To maximize underfill adhesion and minimize delamination, the chip substrate layer is treated prior to the application of the underfill. One typical treatment is to apply energetic Ar/O₂ plasma to clean and activate the substrate. Other treatments can be used in place of energetic plasma, such as applying chemical adhesion promoters to the substrate. Treating the substrate can improve yield in successive processes by up to 25% in some circumstances—depending on chip size—due to improvement in the adhesion properties between the underfill and the chip substrate.

Monitoring the quality of the surface treatment process before starting the underfill process is important, because the cost of the chip module at this stage is very high. Therefore, there is an interest and motivation in monitoring each package before applying the underfill. Monitoring assures that the treatment step is successful and that the underfill will adhere strongly to the treated substrate.

One method for measuring surface energy status, particularly following a surface treatment such as the application of plasma, is to measure the wetting angle. This is done by dispensing a drop of liquid to the surface of the substrate and observing how well the liquid wets the surface. Conflicting forces of cohesion and adhesion will result in the liquid drop having a differing shape depending on the properties of the surface. Monitoring equipment determines the shape of the liquid drop and determines whether its interaction with the surface is within acceptable parameters for a treated substrate.

FIG. 1 illustrates a drop of liquid 102 dispensed onto a surface 104. A contact angle θ_{c}, known as the “wetting angle,” is formed at the point where the edge of the drop 102 meets the surface 104. According to Young's equation, this wetting angle depends on the surface energies of the solid-gas interface (γ_{SG}), liquid-gas interface (γ_{LG}), and solid-liquid interface (γ_{SL}) as follows:

γ_{SG}=γ_{SL}+γ_{LG}cos(θ_{C}) (1)

A substrate treated to maximize wetting by the underfill has a significantly lower wetting angle θ_{c} than a drop of underfill dispensed to an untreated substrate. It is therefore known in the art to dispense a drop of underfill to the surface of the chip substrate and measure the resulting wetting angle. If the wetting angle is below a threshold value, then the substrate is considered treated enough to apply the underfill.

Prior art methods for measuring the wetting angle of a drop of liquid dispensed to the surface of a substrate include using a goniometer and a side microscope to measure the angle from the side. This is the “sessile drop test.” Another method, using the “sessile drop test,” records a side image of the drop and uses computer image analysis to determine the intersection of the bottom surface line and drop tangent line in order to find the wetting angle. Axisymmetric drop shape analysis (ADSA) uses numerical methods to fit Laplace capillary equations to the shape of the drop as seen from the side.

All these methods require a side view of the drop, which most standard dispensing equipment is not capable of performing within standard manufacturing line equipment. Hence, to monitor the wetting angle using any of these methods, one must remove a module from the packaging line and test it on a separate unit. These methods are therefore primarily suitable for spot-checking, as it would be unreasonably time-consuming to remove and test each module individually with any of these methods.

What is needed is an in-line monitoring method that adapts existing equipment to provide a wetting angle measurement for each chip substrate without disrupting the process line.

### SUMMARY

Systems and methods for determining whether to apply liquid adhesive to a chip substrate using in-line monitoring are disclosed. According to an embodiment of the present disclosure the method can include treating a chip substrate surface, for example, by treating the chip substrate surface with energetic plasma, and dispensing at least one liquid adhesive drop on the chip substrate surface. The method can include capturing a top-down image of the liquid adhesive drops and calculating the wetting angle between the liquid adhesive drops and the chip substrate surface based on image data and volume data for liquid adhesive drops. The method can include determining whether to apply the liquid adhesive to the chip substrate based on the calculated wetting angle against predetermined parameters.

In accordance with other aspects of this embodiment, the method can further include receiving the volume data for the at least one liquid adhesive drop from a dispenser; and applying by the dispenser the liquid adhesive to the chip substrate.

In accordance with further aspects of this embodiment, the method can also include aligning the dispenser for application of the liquid adhesive layer to the chip substrate based on the captured top-down image.

In accordance with other aspects of this embodiment, the method can also include calculating a plurality of wetting angles from a plurality of liquid adhesive drops dispensed on the chip substrate surface. The determining step may include comparing the plurality of calculated wetting angles to a threshold angle.

In accordance with other aspects of this embodiment, the method can also include adhering the chip to an integrated circuit package with the liquid adhesive.

In accordance with further aspects of this embodiment, the method can also include providing a plurality of solder bumps to electrically couple the chip to the integrated circuit package; and applying the liquid adhesive as an underfill around the plurality of solder bumps.

In accordance with other aspects of this embodiment, the method can also include generating an alert when the calculated wetting angle does not meet the predetermined parameters.

In accordance with other aspects for this embodiment, treating the chip substrate surface can include cleaning and activating the chip substrate surface with energetic plasma.

In accordance with another embodiment, an article of manufacture is disclosed including at least one processor readable storage medium and instructions stored on the at least one medium. The instructions can be configured to be readable from the at least one medium by at least one processor and thereby cause the at least one processor to operate so as to carry out any and all of the steps in the above-described method.

In accordance with another embodiment, the techniques may be realized as a system comprising one or more processors communicatively coupled to a network; wherein the one or more processors are configured to carry out any and all of the steps described with respect to any of the above embodiments.

The present invention will now be described in more detail with reference to particular embodiments thereof as shown in the accompanying drawings. While the present disclosure is described below with reference to particular embodiments, it should be understood that the present disclosure is not limited thereto. Those of ordinary skill in the art having access to the teachings herein will recognize additional implementations, modifications, and embodiments, as well as other fields of use, which are within the scope of the present disclosure as described herein, and with respect to which the present disclosure may be of significant utility.

### BRIEF DESCRIPTION OF THE DRAWINGS

In order to facilitate a fuller understanding of the present disclosure, reference is now made to the accompanying drawings, in which like elements are referenced with like numerals. These drawings should not be construed as limiting the present disclosure, but are intended to be illustrative only.

FIG. 1 illustrates a liquid drop dispensed on a surface, the associated surface energies, and the wetting angle between the solid-liquid and liquid-gas interfaces.

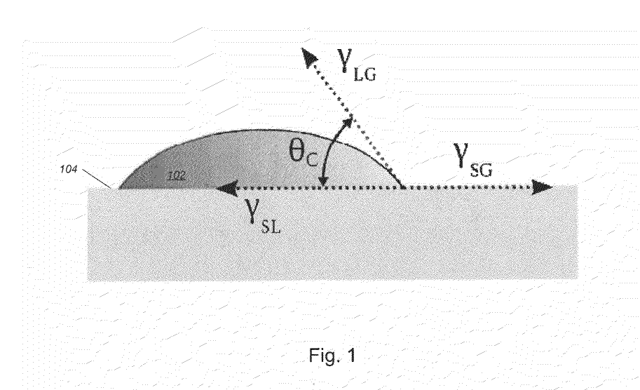

FIG. 2 shows a model of a liquid drop as a spherical cap.

FIG. 3 shows an exemplary method for in-line wetting angle monitoring in accordance with embodiments of the present disclosure.

FIG. 4 shows a top-down computer image of liquid drops marked up to illustrate computer analysis of the image.

FIG. 5 is a chart illustrating data for an exemplary set of trials of computer-measured diameters for drops on both plasma-treated and non-treated surfaces plotted according to a normal distribution.

### DETAILED DESCRIPTION

The present disclosure describes a monitoring process for a “flip chip” line manufacturing procedure. The monitoring occurs after cleaning the chip substrate and before applying an adhesive underfill. The underfill dispensing equipment dispenses one or more drops of underfill to the surface of the chip substrate, then makes an indirect measurement of a wetting angle without removing the semiconductor package from the line to get a side view. Instead, existing dispensing equipment is adapted to calculate the wetting angle from a top-down image.

The above analysis of Young's equation omits the gravity effect on the drop shape. When a liquid drop is within a gravity field, it is necessary to check the effect of this field and the relation between the gravity force and the surface tension of the liquid. If the effect of gravity should be taken into account, the drop's shape is disturbed and the wetting angle is different from the one described by Young's equation above. The relation between gravity and the surface tension is described by Bond's number, given by the equation below:

$$Bo = \frac{ρ \cdot g \cdot {d}^{2}}{γ} \qquad ( 2 )$$

where ρ is the liquid density, g is gravitation acceleration, γ is the surface tension of the liquid, and d is the diameter of the drop. For purposes of underfill dispensed to the chip substrate, we can assume a Bond number significantly less than 1, for example, on the order of 0.001. When the Bond number is much less than unity, the governing mechanism for determining the shape of the liquid drop is the surface tension, and we can neglect the gravity effect in the analysis.

Additionally, the parameters of the analysis allow for the additional assumptions that 0°<θ_{c}<90° and that there will not be significant liquid evaporation during the time frame of the monitoring process. Under these assumptions, it is possible to estimate the wetting angle θ_{c} from a top-down image of the drop.

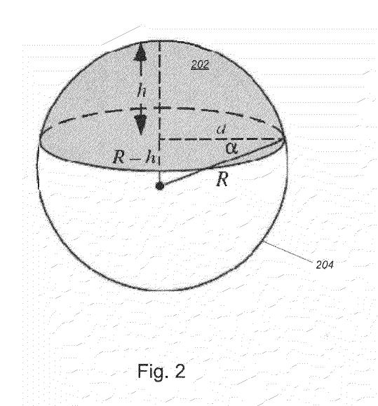

FIG. 2 shows a drop 202 modeled as a spherical cap—that is, as the upper portion of a sphere 204. The drop 202 has a radius “a” 208 and height “h” and is the cap of a sphere of radius R. Its volume V_{Cap} can be calculated as:

$${V}_{Cap} = \frac{π}{3} * {h}^{2} ( 3 R - h ) \qquad ( 3 )$$

In terms of the angle, α, measured between the sphere radius R and the drop radius “a” 208:

$${V}_{Cap} = \frac{π}{3} * {R}^{3} ( 1 - 3 sin α + {sin}^{3} α ) \qquad ( 4 )$$

The wetting angle θ_{c} is complementary to α 206 such that θ_{c}+α=π/2. Substituting for θ_{c}, the equation becomes:

$${V}_{Cap} = \frac{π}{3} * {R}^{3} ( 1 - 3 cos {θ}_{c} + {cos}^{3} {θ}_{c} ) \qquad ( 5 )$$

We can also see that α 206 is the cosine angle for a right triangle with drop radius “a” 208 as the near side and sphere radius R as the hypotenuse, which allows us to substitute for R=a/cos(α)=a/sin(θ_{c}):

$${V}_{Cap} = \frac{π}{3} * {a}^{3} \frac{( 1 - 3 cos {θ}_{c} + {cos}^{3} {θ}_{c} )}{{sin}^{3} {θ}_{c}} \qquad ( 6 )$$

Equation 6 allows solving for θ_{c} using only two values: the volume V_{Cap} and radius “a” 208 of the spherical cap.

When dispensing a drop onto the substrate, standard dispensing equipment tightly controls the volume of the drop with high accuracy. Therefore, the measured diameter of the drop as seen by a top-view inspection camera, for example, a camera already used in-line to adjust and align dispensing displacement, is sufficient to calculate the wetting angle θ_{c}.

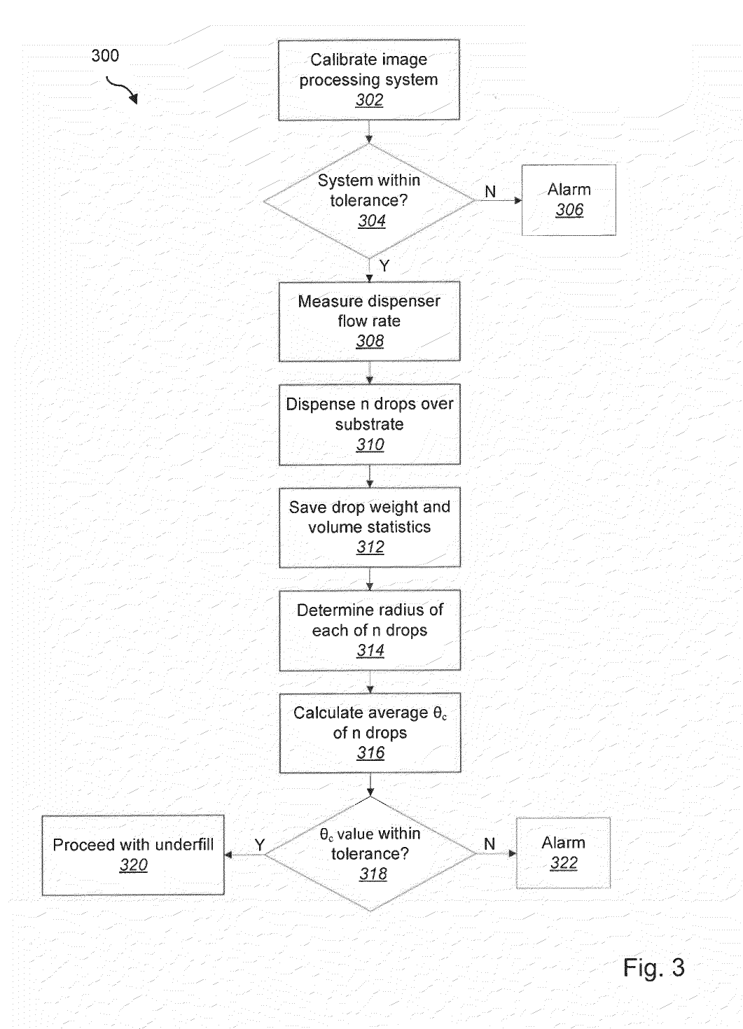

FIG. 3 is a flow chart illustrating a method 300 for monitoring a substrate prior to underfill according to some implementations of the present disclosure. The method 300 allows the use of dispensing and imaging equipment standard to the manufacturing line, in conjunction with novel techniques as described herein, to calculate the wetting angle of a dispensed drop from a top-down image.

Initially, the image processing system is calibrated (302). This process can require user assistance or can be automatic. The calibration process can, for example, set the distance between a camera and the substrate so that the image processing logic can accurately determine distances on the substrate from recorded images. As part of calibrating the system, one or more diagnostics can be performed to assure that the system is operating within allowed tolerances (304). If the calibration fails, an alarm can sound (306), potentially halting or delaying later steps in the manufacturing procedure while the issue is resolved.

If the image processing system is properly calibrated, then the system proceeds to measure the dispenser flow rate (308). The measurement process can involve conducting one or more quality assurance tests on the dispenser to assure that it operates within a known flow rate, or can involve capturing information about the dispenser's flow rate.

The dispenser is then used to dispense a number (“n”) of drops of the underfill over the substrate (310). The drops can be spaced so as to be distinctly imaged by the system without interfering with each other. The number “n” of drops that are dispensed can be set based on a cost-benefit analysis; measuring more drops can require more time, particularly if the system is testing every substrate, but can increase the confidence level of the monitoring process. In some implementations, three to thirty drops are dispensed.

Based on the dispenser flow rate and output, the drop weight and volume statistics are calculated and stored in the system (312). Because the precision of the dispenser is high and the properties of the fluid are precisely known, the volume and weight of each drop can also be known and registered by the system.

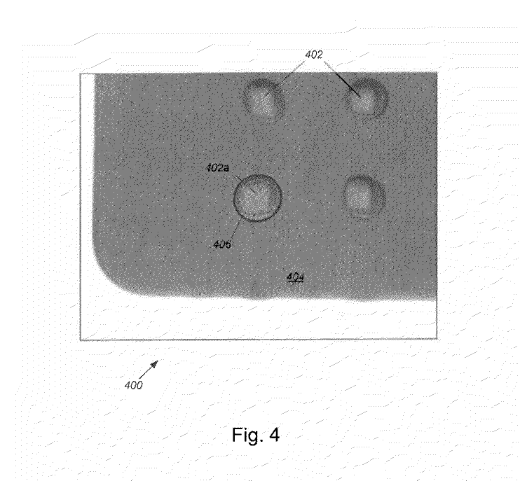

Based on a top-down camera image, the radius of each of the “n” drops is determined (314). This can involve any appropriate computer vision and analysis techniques known in the art. As one example, FIG. 4 is an exemplary image 400 showing drops 402 dispensed on a substrate 404. A computer algorithm has fitted a circle 406 to the image of the lower left drop 402a, and calculates the radius of that drop 402a based on the fitted circle 406.

Returning to FIG. 3, an average wetting angle θ_{c} is calculated based on the radius and volume of each of the “n” drops (316). This can be done using equation 6 above, as both the V_{cap} and “a” values are known so that θ_{c} is the only unknown value and can be solved for.

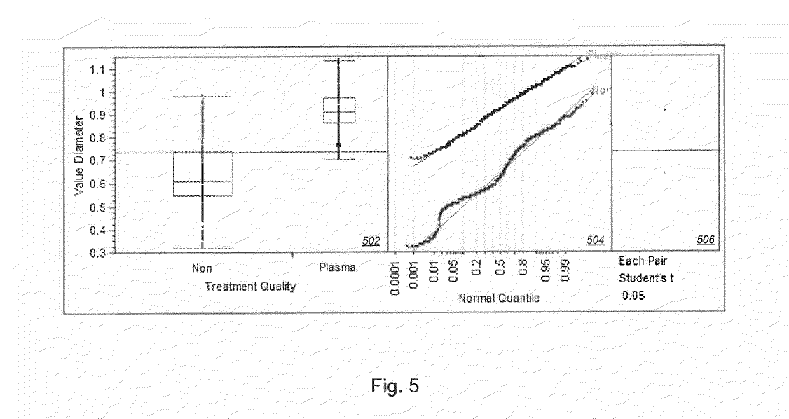

The average θ_{c} value (or any other selected property such as the median θ_{c} value, minimum θ_{c} value, maximum θ_{c} value etc.) can then be compared with set threshold values to see if it falls within the parameters of a clean substrate (318). The threshold values for the wetting angle can be set experimentally, as further described below with respect to FIG. 5. If the wetting angle falls within the acceptable range, then the system can continue the manufacturing process by applying the underfill (320). If not, then an alarm can sound (322), which can prompt a user or an automated process to remove the substrate from the line, to repeat one or more cleaning steps, or to take some action other than allowing the substrate to proceed to apply the underfill.

According to aspects of the present disclosure, the disclosed system and method can align the dispenser before applying the liquid adhesive layer to the chip substrate based on the captured image 400. The disclosed system and method can also apply a set of solder bumps to electrically connect the chip to the integrated circuit package.

Experimental results have confirmed that drop radius can be used for distinguishing between contaminated and clean substrates. FIG. 5 shows a set of measurements for drop diameter for underfill drops dispensed on a chip substrate both before and after the substrate is treated with Ar-O₂ plasma. The substrate before treatment corresponds to a contaminated substrate, while the substrate after treatment is a clean substrate. The first chart 502 shows a vertical plot of the measured diameters of the drops, in millimeters, separated between the non-treated and plasma-treated substrates. The boxes are drawn around the central 50% of the data points, representing all of the values between the twenty-fifth and seventy-fifth percentile for diameter. Lines are also drawn at the maximum, minimum, and median values. The diameter data reflected in the first chart 502 is also shown in the following table:

TABLE 1
Quantiles for drop diameter measurements (in mm)

| Treatment | Maximum | 90% | 75% | Median | 25% | 10% | Minimum |
|---|---|---|---|---|---|---|---|
| Non | 0.98 | 0.795 | 0.74 | 0.61 | 0.55 | 0.53 | 0.32 |
| Plasma | 1.13 | 1.01 | 0.97 | 0.91 | 0.86 | 0.8 | 0.7 |

As shown on Table 1, the maximum value measured for the diameter of a drop on a non-treated substrate was 0.98 mm, while the maximum value measured for the diameter of a drop on a plasma-treated substrate was 1.13 mm. 90% of drops on non-treated substrates measured less than 0.795 mm. The median size of a drop diameter on a non-treated substrate was 0.61 mm.

Also as shown on Table 1, the minimum value measured for the diameter of a drop on a plasma-treated substrate was 0.7 mm, while the minimum value measured for the diameter of a drop on a non-treated substrate was 0.32 mm. 10% of drops on a plasma-treated substrate measured less than 0.8 mm in diameter. The median size of a drop diameter on a treated substrate was 0.91 mm.

The second chart 504 shows the same data points spread out along a horizontal axis representing the data point's quantile position against the rest of the points for its treatment type. The x-axis is not linear, but instead is scaled according to the standard deviation of each point from the mean, such that a normally-distributed data set would appear as a straight line on the chart 504. The third chart 506 represents the results of a statistical t-test applied to the two populations (the set of results before treatment and the set of results after treatment). This test determines whether the two populations are significantly different given the result distribution. The result here shows two circles, placed around the “value diameter” average with a circumference relative to the standard deviation. The circles are clearly separated—which indicate two significantly different populations.

Table 2 below shows the median, 5%, and 95% quantiles for diameter of both non-treated and plasma-treated groups, along with the calculated wetting angle associated with each diameter, for a test performed on a particular underfill material, plasma treatment, and substrate.

TABLE 2
Quantiles for diameter and wetting angle

| | | | Calculated Wetting |
|---|---|---|---|
| Group | Quantiles | Diameter [mm] | Angle [°] |
| Non-treated | 95% | 0.82 | 18.873 |
| Non-treated | Median | 0.61 | 42.412 |
| Non-treated | 5% | 0.5 | 65.954 |
| Plasma-treated | 95% | 1 | 10.538 |
| Plasma-treated | Median | 0.91 | 13.925 |
| Plasma-treated | 5% | 0.8 | 20.2677 |

Based on the data shown above, for the tested materials and treatment, a wetting angle threshold of between 18° and 20° would prompt a system alarm for approximately 95% of the untreated (contaminated) substrates while passing approximately 95% of the treated (clean) substrates. Further refinements could be made to the computer vision software for accurately determining drop radius which can increase the accuracy of the monitoring process.

At this point it should be noted that monitoring in accordance with the present disclosure as described above can involve the processing of input data and the generation of output data to some extent. This input data processing and output data generation can be implemented in hardware or software. For example, specific electronic components can be employed in a mobile device or similar or related circuitry for implementing the functions associated with remote tracking in accordance with the present disclosure as described above. Alternatively, one or more processors operating in accordance with instructions can implement the functions associated with monitoring in accordance with the present disclosure as described above. If such is the case, it is within the scope of the present disclosure that such instructions can be stored on one or more non-transitory processor readable storage media (e.g., a magnetic disk or other storage medium), or transmitted to one or more processors via one or more signals embodied in one or more carrier waves.

The present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. For example, potentially any manufacturing process that uses wetting angle in its calculations could use this to allow for a simple top-down calculation of wetting angle. Thus, such other embodiments and modifications are intended to fall within the scope of the present disclosure. Further, although the present disclosure has been presented herein in the context of at least one particular implementation in at least one particular environment for at least one particular purpose, those of ordinary skill in the art will recognize that its usefulness is not limited thereto and that the present disclosure can be beneficially implemented in any number of environments for any number of purposes. Accordingly, the claims set forth below should be construed in view of the full breadth and spirit of the present disclosure as described herein.

What is claimed is:

1. A computer-implemented method for determining whether to apply liquid adhesive to a chip substrate based on a measured wetting angle, comprising:
treating a chip substrate surface;
dispensing at least one liquid adhesive drop on the chip substrate surface;
capturing by a camera a top-down image of the at least one liquid adhesive drop;
calculating the wetting angle between the at least one liquid adhesive drop and the chip substrate surface based on data from the image of the at least one liquid adhesive drop and volume data for the at least one liquid adhesive drop; and
determining whether to apply a layer of the liquid adhesive to the chip substrate based on evaluating the calculated wetting angle against predetermined parameters.

2. The computer-implemented method of claim 1, further comprising:
receiving the volume data for the at least one liquid adhesive drop from a dispenser; and
applying by the dispenser the liquid adhesive to the chip substrate.

3. The computer-implemented method of claim 2, further comprising:
aligning the dispenser for application of the liquid adhesive layer to the chip substrate based on the captured top-down image.

4. The computer-implemented method of claim 1, further comprising:
calculating a plurality of wetting angles from a plurality of liquid adhesive drops dispensed on the chip substrate surface;
wherein the determining step further comprises comparing the plurality of calculated wetting angles to a threshold angle.

5. The computer-implemented method of claim 1, further comprising:
adhering the chip to an integrated circuit package with the liquid adhesive.

6. The computer-implemented method of claim 5, further comprising:
providing a plurality of solder bumps to electrically couple the chip to the integrated circuit package; and
applying the liquid adhesive as an underfill around the plurality of solder bumps.

7. The computer-implemented method of claim 1, further comprising:
generating an alert when the calculated wetting angle does not meet the predetermined parameters.

8. The computer-implemented method of claim 1, wherein treating the chip substrate surface comprises cleaning and activating the chip substrate surface with energetic plasma.

9. An article of manufacture comprising:
at least one processor readable storage medium; and
instructions stored on the at least one medium;
wherein the instructions are configured to be readable from the at least one medium by at least one processor and thereby cause the at least one processor to operate so as to:
treat a chip substrate surface;
dispense at least one liquid adhesive drop on the chip substrate surface;
capture by a camera a top-down image of the at least one liquid adhesive drop;
calculate the wetting angle between the at least one liquid adhesive drop and the chip substrate surface based on data from the image of the at least one liquid adhesive drop and volume data for the at least one liquid adhesive drop; and
determine whether to apply a layer of the liquid adhesive to the chip substrate based on evaluating the calculated wetting angle against predetermined parameters.

10. The article of claim 9, wherein the instructions are further configured to cause the processor to:
receive the volume data for the at least one liquid adhesive drop from a dispenser; and
apply by the dispenser the liquid adhesive to the chip substrate.

11. The article of claim 10, wherein the instructions are further configured to cause the processor to:
align the dispenser for application of the liquid adhesive layer to the chip substrate based on the captured top-down image.

12. The article of claim 9, wherein the instructions are further configured to cause the processor to:
calculate a plurality of wetting angles from a plurality of liquid adhesive drops dispensed on the chip substrate surface;
wherein the determining step further comprises comparing the plurality of calculated wetting angles to a threshold angle.

13. The article of claim 9, wherein the instructions are further configured to cause the processor to:
adhere the chip to an integrated circuit package with the liquid adhesive.

14. The article of claim 13, wherein the instructions are further configured to cause the processor to:
electrically connect the chip to the integrated circuit package with a plurality of solder bumps; and
apply the liquid adhesive as an underfill around the solder bumps.

15. The article of claim 9, wherein the instructions are further configured to cause the processor to:
generate an alert when the calculated wetting angle does not meet the predetermined parameters.

16. A system comprising:
one or more processors communicatively coupled to a network; wherein the one or more processors are configured to:
treat a chip substrate surface;
dispense at least one liquid adhesive drop on the chip substrate surface;
capture by a camera a top-down image of the at least one liquid adhesive drop;
calculate the wetting angle between the at least one liquid adhesive drop and the chip substrate surface based on data from the image of the at least one liquid adhesive drop and volume data for the at least one liquid adhesive drop; and
determine whether to apply a layer of the liquid adhesive to the chip substrate based on evaluating the calculated wetting angle against predetermined parameters.

17. The system of claim 16, wherein the one or more processors are further configured to:
receive the volume data for the at least one liquid adhesive drop from a dispenser; and
apply by the dispenser the liquid adhesive to the chip substrate.

18. The system of claim 17, wherein the one or more processors are further configured to:
align the dispenser for application of the liquid adhesive layer to the chip substrate based on the captured top-down image.

19. The system of claim 16, wherein the one or more processors are further configured to:
calculate a plurality of wetting angles from a plurality of liquid adhesive drops dispensed on the chip substrate surface;
wherein the determining step further comprises comparing the plurality of calculated wetting angles to a threshold angle.

20. The system of claim 16, wherein the one or more processors are further configured to:
adhere the chip to an integrated circuit package with the liquid adhesive.
